(19) United States
(12) Patent Application Publication
(10) Pub. No.: US 2025/0062202 A1
(43) Pub. Date: Feb. 20, 2025

(54) PACKAGE STRUCTURE, SEMICONDUCTOR DIE AND METHOD OF MANUFACTURING THE SAME

(71) Applicant: Taiwan Semiconductor Manufacturing Company, Ltd., Hsinchu (TW)

(72) Inventors: Chun-Yi Sung, Hsinchu (TW); Ta-Hsuan Lin, Hsinchu City (TW); Hua-Wei Tseng, New Taipei City (TW); Mill-Jer Wang, Hsinchu (TW)

(73) Assignee: Taiwan Semiconductor Manufacturing Company, Ltd., Hsinchu (TW)

(21) Appl. No.: 18/451,105

(22) Filed: Aug. 17, 2023

(51) Int. Cl. H01L 23/498; H01L 23/00; H01L 25/065

(52) U.S. Cl. CPC H01L 23/49822; H01L 23/49816; H01L 24/32; H01L 24/48; H01L 25/0657; H01L 2224/32014; H01L 2224/32235; H01L 2224/48132; H01L 2224/48157; H01L 2225/06506; H01L 2225/06541; H01L 2924/1435; H01L 2924/182

(57) ABSTRACT

A semiconductor die and methods of forming the same and a package structure are provided. The semiconductor die includes a semiconductor substrate, a plurality of conductive pads over the semiconductor substrate, a passivation layer over the semiconductor substrate and partially covering the plurality of conductive pads, an interconnecting line disposed on the passivation layer, and a plurality of connectors disposed on and electrically connected to the plurality of conductive pads. Each of the plurality of connectors includes a stacked structure of a first conductive pillar and a second conductive pillar disposed directly on the first conductive pillar, wherein a span of the second conductive pillar is smaller than a span of the first conductive pillar, and an orthogonal projection of the second conductive pillar falls within an orthogonal projection of the first conductive pillar, and the interconnecting line is located beside and spaced apart from the plurality of connectors.

### BACKGROUND

The semiconductor industry has experienced rapid growth due to continuous improvements in the integration density of various electronic components. For the most part, this improvement in integration density has come from repeated reductions in minimum feature size, which allows more of the smaller components to be integrated into a given area. In the meantime, more functions need to be integrated into the semiconductor dies. Accordingly, the semiconductor dies need to have increasingly greater numbers of pads packed into smaller areas, and the density of the pads rises over time.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A to FIG. 1N are schematic cross-sectional views and schematic top views illustrating a method of forming a die according to some embodiments of the disclosure.

FIG. 2A to FIG. 2E are schematic cross-sectional views illustrating a method of forming a package structure according to some embodiments of the disclosure.

FIG. 3 is a schematic cross-sectional view illustrating a package structure according to some embodiments of the disclosure.

### DESCRIPTION OF THE EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and/or the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

It should be appreciated that the following embodiment(s) of the present disclosure provides applicable concepts that can be embodied in a wide variety of specific contexts. The specific embodiment(s) discussed herein is merely illustrative and is related to a three-dimensional (3D) integration structure or assembly, and does not limit the scope of the present disclosure. Embodiments of the present disclosure describe the exemplary manufacturing process of 3D stacking structures and the 3D stacking structures fabricated there-from. Certain embodiments of the present disclosure are related to the 3D stacking structures formed with wafer bonding structures and stacked wafers and/or dies. Other embodiments relate to 3D integration structures or assemblies including post-passivation interconnect (PPI) structures or interposers with other electrically connected components, including wafer-to-wafer assembled structures, die-to wafer assembled structures, package-on-package assembled structures, die-to-die assembled structures, and die-to-substrate assembled structures. The wafers or dies may include one or more types of integrated circuits or electrical components on a bulk semiconductor substrate or a silicon/germanium-on-insulator substrate. The embodiments are intended to provide further explanations but are not used to limit the scope of the present disclosure.

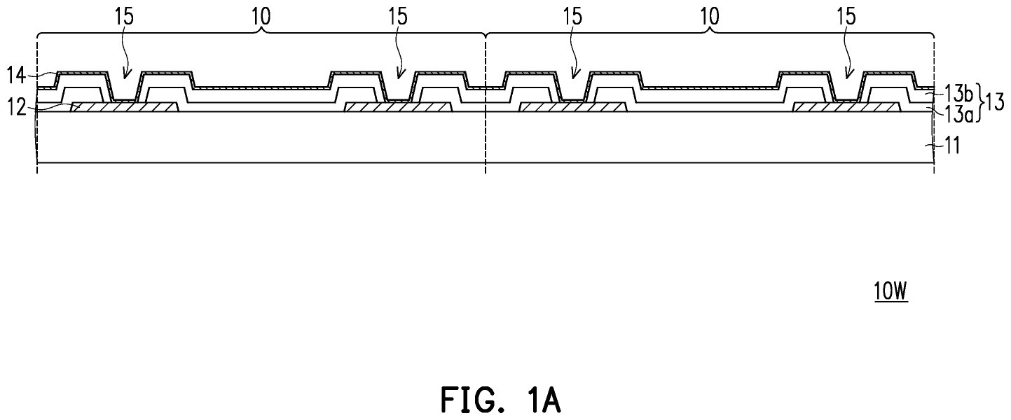

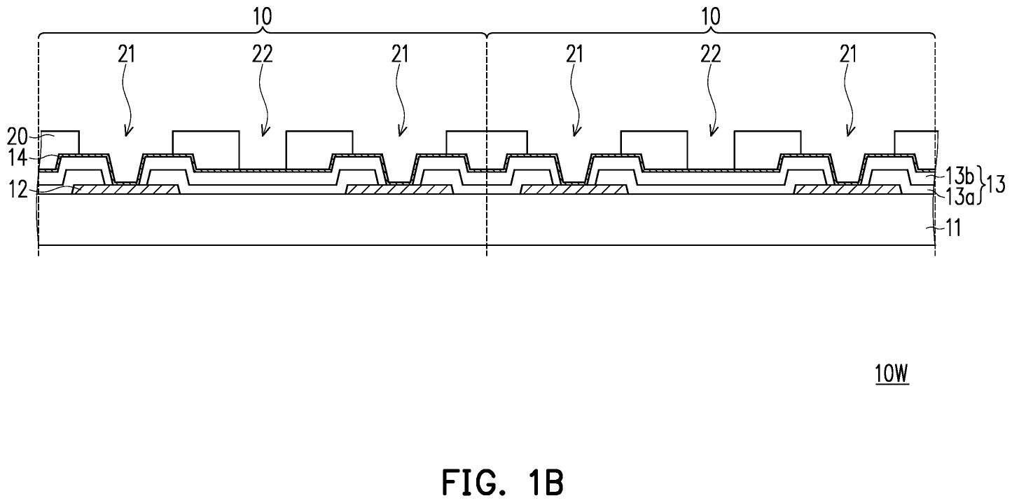

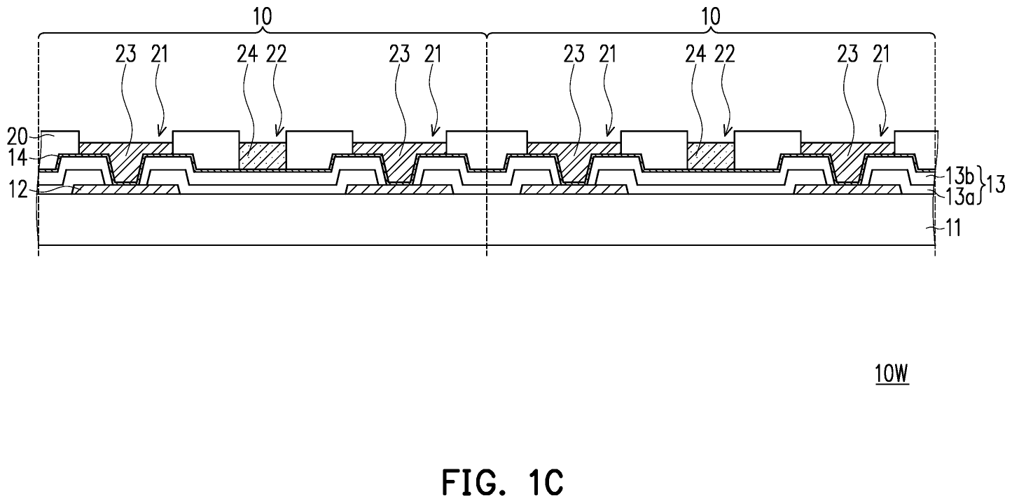

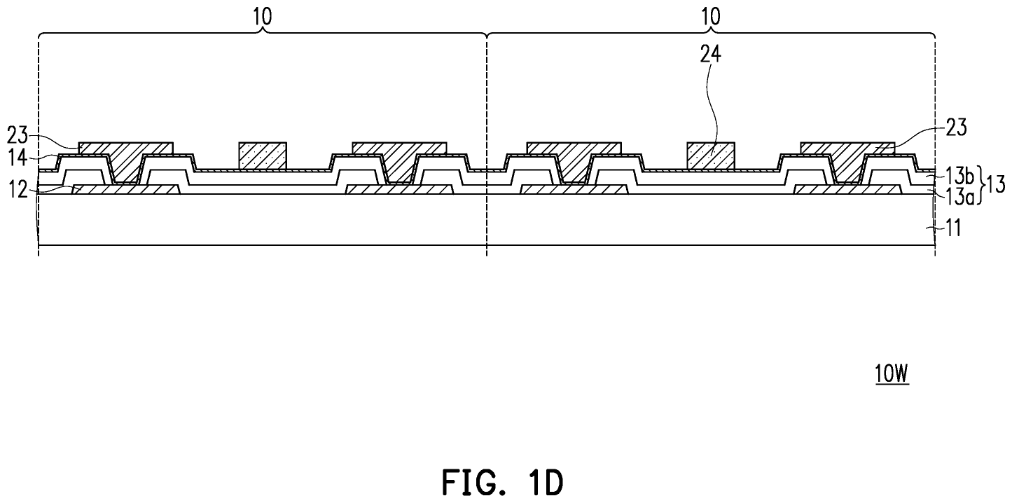

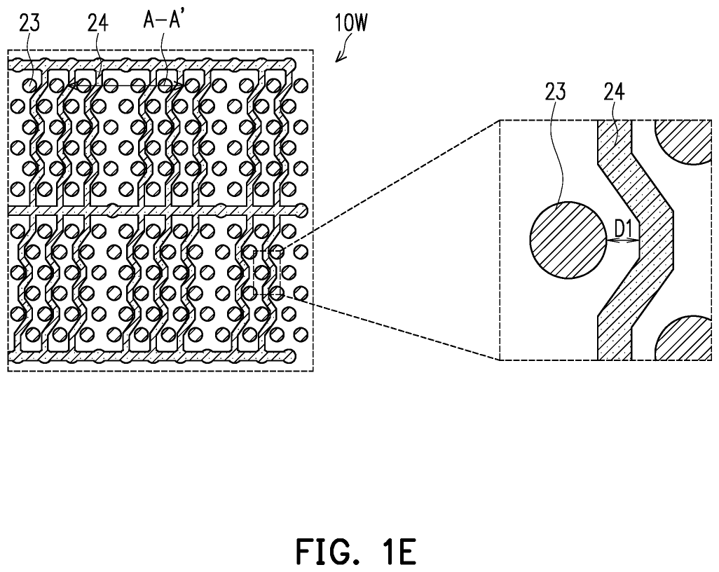

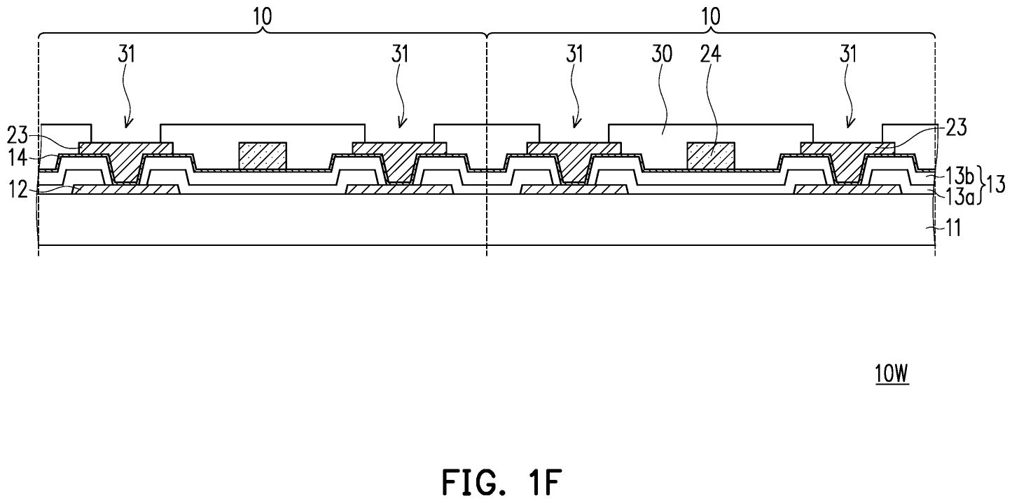

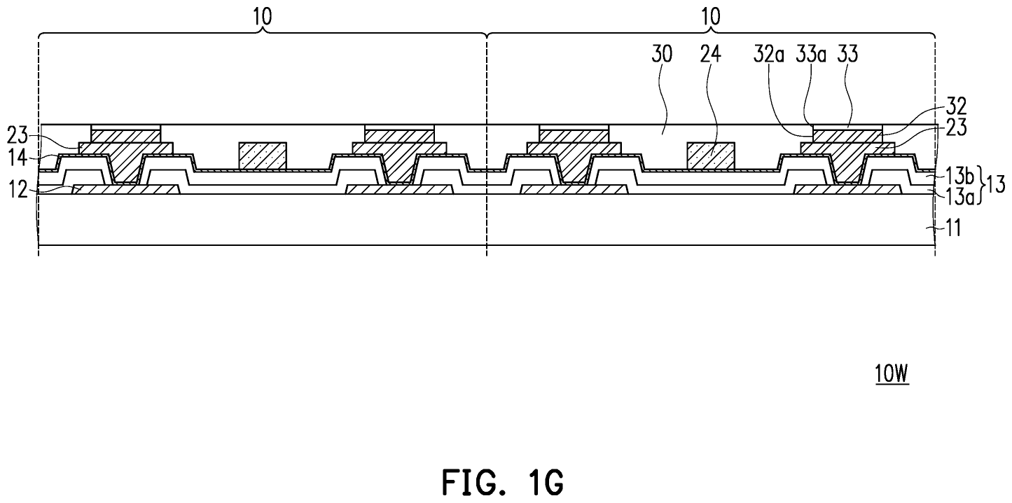

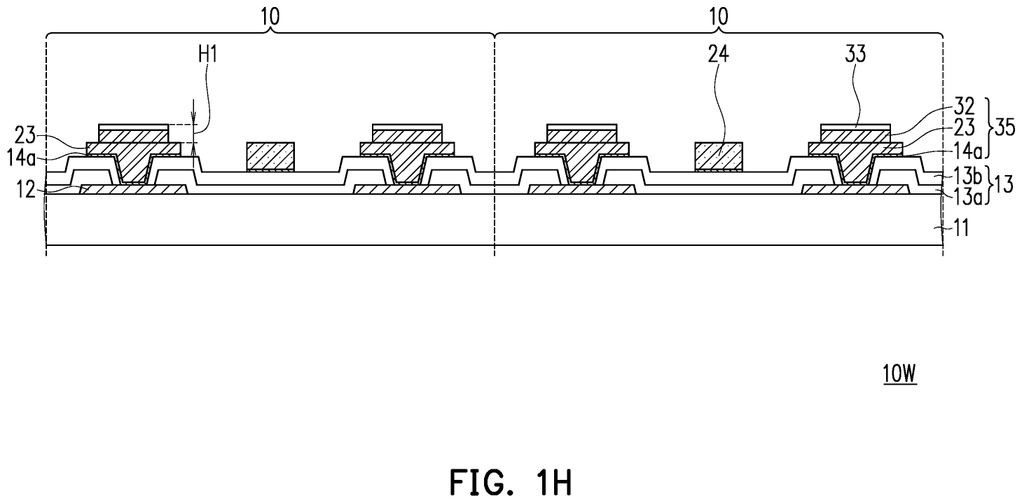

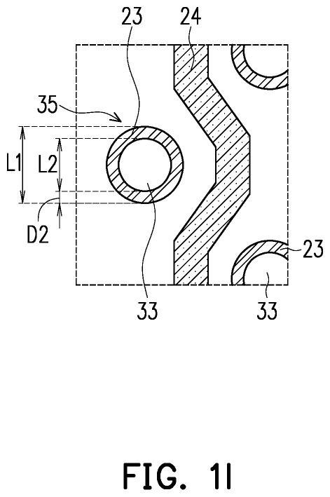

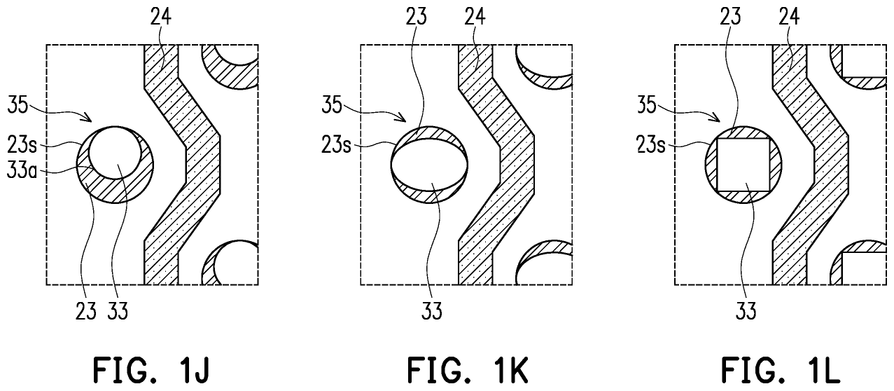

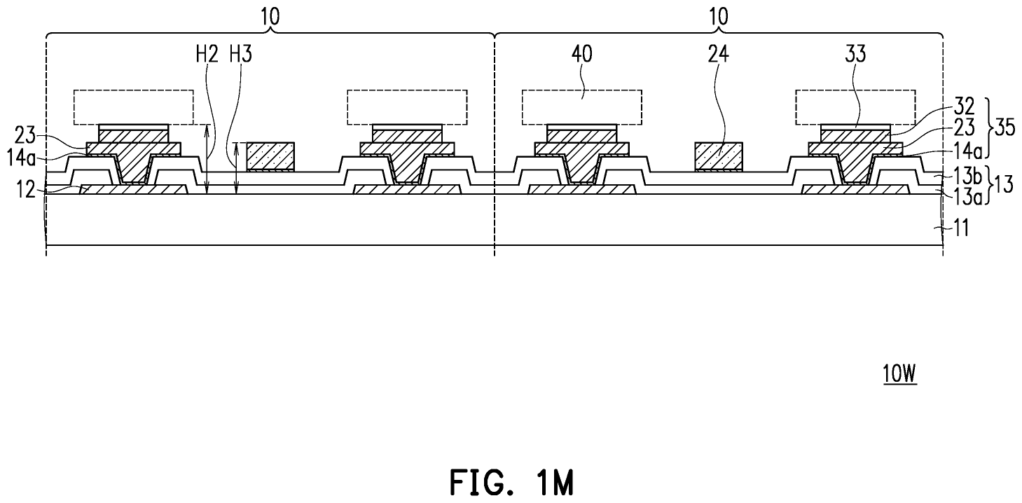

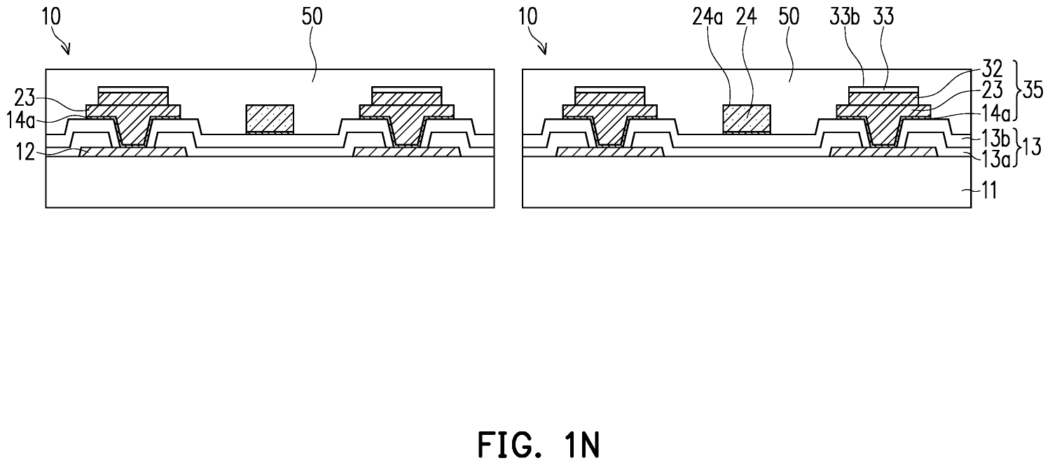

FIG. 1A to FIG. 1N are schematic cross-sectional views and schematic top views illustrating a method of forming a die according to some embodiments of the disclosure.

Referring to FIG. 1A, a wafer 10W including a plurality of dies (or die units) 10 is provided. For the sake of brevity, two dies 10 are shown. In some embodiments, the dies 10 are arranged in an array in the wafer before a die-saw process is performed, but the disclosure is not limited thereto. In some other embodiments, the die 10 is provided after the die saw process is performed. That is, the die 10 may have been cut from a wafer.

In some embodiments, the die 10 includes a substrate 11, a pad 12 and a passivation layer 13. In some embodiments, the substrate 11 is made of silicon or other semiconductor materials. Optionally, the substrate 11 includes other elementary semiconductor materials such as germanium, gallium arsenic, or other suitable semiconductor materials. In some embodiments, the substrate 11 may further include other features such as various doped regions, a buried layer, and/or an epitaxy layer. Moreover, in some embodiments, the substrate 11 is made of an alloy semiconductor such as silicon germanium, silicon germanium carbide, gallium arsenic phosphide, or gallium indium phosphide. Furthermore, the substrate 11 may be a semiconductor on insulator such as silicon on insulator (SOI) or silicon on sapphire.

In some embodiments, devices (not shown) are formed in or on the substrate 11. In some embodiments, the devices may be active devices, passive devices, or a combination thereof. In some embodiments, the devices are integrated circuit devices. The devices are, for example, transistors, capacitors, resistors, diodes, photodiodes, fuse devices, or the like. In some embodiments, the interconnection structure (not shown) and the dielectric structure (not shown) are formed in or on the substrate 11. In some embodiments, the interconnection structure includes multiple layers of metal lines and plugs. The metal lines and plugs include conductive materials, such as metal, metal alloy or a combination thereof. For example, the conductive material may include tungsten (W), copper (Cu), copper alloys, aluminum (Al), aluminum alloys, or combinations thereof.

The conductive pads 12 are formed on the substrate 11. The conductive pads 12 are electrically connected to the interconnect structure (not shown) to provide an external connection of the die 10. In some embodiments, the conductive pads 12 are located on or part of top metallization features of the interconnect structure of the die unit. The material of the conductive pads 12 may include metal or metal alloy, such as aluminum, copper, nickel, or alloys thereof. In one embodiment, the conductive pads 12 are aluminum pads.

The passivation layer 13 is formed over the substrate 11 and covers a portion of the conductive pads 12. A portion of the conductive pads 12 is exposed by the passivation layer 13 and serves as an external connection of the die 10. The passivation layer 13 includes an insulating material such as silicon oxide, silicon nitride, polymer, or a combination thereof. The polymer is, for instance, polybenzoxazole (PBO), polyimide (PI), benzocyclobutene (BCB), a combination thereof, or the like. The passivation layer 13 has an opening 15 exposing a portion of the conductive pads 12. The passivation layer 13 may be a single-layer structure or a multi-layer structure.

In some embodiments, the passivation layer 13 is a bi-layer structure and includes a first passivation sublayer 13a and a second passivation sublayer 13b on the first passivation sublayer 13a. The material of the first passivation layer 13a and the material of the second passivation sublayer 13b may be the same or different. In some embodiments, the second passivation sublayer 13b is also referred to as a post-passivation layer, and is optionally formed. In some embodiments, the first passivation sublayer 13a may be a silicon oxide layer, a silicon nitride layer, a silicon oxy-nitride layer or a dielectric layer formed by other suitable dielectric materials. The second passivation sublayer 13b may be a polymer layer such as including PBO, PI, BCB, combinations thereof or the like. However, the disclosure is not limited thereto.

A seed layer 14 is formed over the substrate 11 by a physical vapor deposition (PVD) process such as a sputtering process. In some embodiments, the seed layer 14 may be a copper seed layer or other suitable metal layer. The material of the seed layer 14 may include, titanium (Ti), titanium tungsten (TiW), tantalum (Ta), copper (Cu), combinations thereof or the like. The seed layer 14 may be a single layer structure or a multi-layer structure. In some embodiments, the seed layer 14 includes a first seed layer such as a titanium layer and a second seed layer such as a copper layer on the first seed layer.

In some embodiments, the seed layer 14 conformally covers the conductive pads 12 and the passivation layer 13. That is, the seed layer 14 has a substantially equal thickness extending along the region on which the seed layer 14 is formed. The seed layer 14 is in electrical contact with the conductive pads 12 and further electrically connected to the interconnection structure (not shown) through the conductive pads 12. The seed layer 14 covers the top surfaces of the passivation layer 13 and fills into the openings 15 to cover sidewalls of the passivation layer 13 and the top surfaces of the conductive pads 12 exposed by the openings 15.

Referring to FIG. 1B, a first patterned photoresist layer 20 having first openings 21 and second openings 22 is formed over the substrate 11. The first patterned photoresist layer 20 may be a patterned photoresist, for example. In some embodiments, the first openings 21 are formed directly over the openings 15 (FIG. 1A) of the passivation layer 13, exposing the seed layer 14 covering surfaces of the openings 15 and a portion of the seed layer 14 on the top surface of the passivation layer 13. In some embodiments, the second openings 22 are formed over the seed layer 14, and does not overlap with the openings 15 (FIG. 1A) of the passivation layer 13 on vertical projection. In other words, the first openings 21 overlap with the conductive pads 12 on vertical projection, and the second openings 22 do not overlap with the conductive pads 12 on vertical projection.

Referring to FIG. 1C, first conductive pillars 23 are formed on the seed layer 14 exposed by the first openings 21 of the patterned photoresist layer 20. Interconnecting lines 24 are formed on the seed layer 14 exposed by the second openings 22 of the patterned photoresist layer 20.

In some embodiments, the first conductive pillars 23 and the interconnecting lines 24 may include copper, nickel, combinations thereof, or other suitable metal, and may be formed by plating process, such as electroplating, electroless plating or the like. The first conductive pillars 23 are electrically connected to the conductive pads 12 through the seed layer 14. The interconnecting lines 24 may serve as an interconnect structure for the die 10.

Referring to FIG. 1D, the first patterned photoresist layer 20 (FIG. 1C) is stripped by an ashing process, an etching process such as wet etching or dry etching, for example.

Referring to FIG. 1E, a schematic top view showing the layout and arrangement of the interconnecting lines 24 and the first conductive pillars 23 in the wafer 10W is provided. In some embodiments, the first conductive pillars 23 are arranged in an array within the die units of the wafer 10W, and the interconnecting lines 24 are formed into a grid pattern, but each interconnecting line 24 (one segment) is located beside and spaced apart from the first conductive pillars 23 arranged in-between the grid pattern (without touching the segments of the grid pattern). In some embodiment, FIGS. 1A-1D, 1F-1H, 1M, and IN are schematic cross-sectional views illustrating a cross-section of the exemplary structure as shown in FIG. 1E along the cross-section line A-A′.

In some embodiment, as shown in the enlarged partial top view shown at the right part of FIG. 1E, a distance (the shortest distance) D1 between the sidewall of the first conductive pillar 23 and the sidewall of the nearest interconnecting line 24 is in a range from about 10 μm to about 22.5 μm. Within this range, the distance D1 is large enough to avoid the risks of wrongfully contacting the interconnecting line(s) or even bridging with the interconnecting line(s) 24 during the following probe testing or packaging the dies 10. In some embodiment, as long as the distance between the first conductive pillar 23 and the nearest interconnecting line 24 is short (e.g. less than 20 μm), or a ratio of the dimension (diameter) of the first conductive pillar 23 and the shortest distance between the first conductive pillar 23 and the interconnecting line 24 is large (e.g. larger than 2), it is favorable to form an additional pillar for assisting probe testing.

Referring to FIG. 1F, a second patterned photoresist layer 30 having third openings 31 is formed over the substrate 11. The second patterned photoresist layer 30 may be a patterned photoresist, for example. In some embodiments, the third openings 31 are formed directly over the first conductive pillars 23, exposing a portion of the first conductive pillars 23. In some embodiments, the second patterned photoresist layer 30 covers the interconnecting lines 24. In other words, the third openings 31 overlap with the conductive pads 12 on vertical projection.

Referring to FIG. 1G, second conductive pillars 32 are formed on the first conductive pillars 23 and probe pads 33 are formed on the second conductive pillars 32 exposed by the third openings 31 of the second patterned photoresist layer 30. In some embodiments, the second conductive pillars 32 may include copper, nickel, combinations thereof, or other suitable metal, and may be formed by plating process, such as electroplating, electroless plating or the like. In some embodiments, the material of the second conductive pillar 32 and the material of the first conductive pillar 23 are the same. In some embodiments, the material of the second conductive pillar 32 and the material of the first conductive pillar 23 may be different. The second conductive pillars 32 are electrically connected to the conductive pads 12 through the first conductive pillars 23 and the seed layer 14.

In some embodiments, the probe pads 33 are formed on the second conductive pillars 32 for verification testing such as testing process in the subsequent process. The probe pad 33 includes conductive materials. In some embodiments, the probe pad 33 is a solder layer including tin or tin alloy. The probe pad 33 may be formed by plating process, such as electroplating, electroless plating or the like. In some embodiments, the sidewalls 33a of the probe pad 33 are aligned with the sidewalls 32a of the second conductive pillar 32.

Referring to FIG. 1H, the second patterned photoresist layer 30 (FIG. 1G) is removed (stripped) by an ashing process, or an etching process such as wet etching or dry etching, for example. An etching process using the first conductive pillars 23, the second conductive pillars 32 and the probe pads 33 as a mask is performed, so as to remove the seed layer 14 not covered by the first conductive pillar 23 to form a patterned seed layer 14a underlying the first conductive pillar 23. The individual connector 35 is constituted of the patterned seed layer 14a, the first conductive pillar 23, and the second conductive pillar 32 stacked in sequence (from bottom to top). The etching process may include dry etching, wet etching, or a combination thereof. In some embodiments, the etching process is performed with a high etching selectivity ratio of the seed layer 14 to the first conductive pillar 23, and the first conductive pillar 23 is substantially not etched during the etching process. It is understood that, the number of the connectors 35 shown in the die 10 is merely for illustration, and the disclosure is not limited thereto.

FIG. 1I is a schematic enlarged top view showing the relative positions and configurations of the probe pads 33 and the underlying first conductive pillars 23 of the connectors 35. Referring to FIG. 1I, a span of each probe pad 33 is substantially the same as the span of the corresponding underlying second conductive pillar 32 (not shown in the top views as directly below the probe pad 33), and the span of both is smaller than a span of the first conductive pillar 23. From the schematic top view, an orthogonal projection of the individual probe pad 33 (and of the individual second conductive pillar 32) falls within an orthogonal projection of the corresponding underlying first conductive pillar 23. In some embodiment, the probe pads 33, the second conductive pillars 32, and the first conductive pillar 23 are of round or elliptical shapes, and the first conductive pillar 23 and the second conductive pillar 32 (together with the probe pads 33) are arranged concentrically (with overlapped centers).

In some embodiments, a diameter (or width) L1 of the first conductive pillar 23 is greater than a diameter (or width) L2 of the second conductive pillar 32. For example, the width L1 of the first conductive pillar 23 is in a range from 40 μm to 50 μm, and the width L2 of the second conductive pillar 32 is in a range from 30 μm to 40 μm. That is, a distance D2 between a sidewall of the first conductive pillar 23 and a sidewall of the second conductive pillar 32 is in a range from 1 μm to 5 μm. In some embodiment, as long as the distance between the first conductive pillar 23 and the nearest interconnecting line 24 is short (e.g. less than 22.5 μm or less than 20 μm), or a ratio of the dimension (diameter) of the first conductive pillar 23 and the shortest distance between the first conductive pillar 23 and the interconnecting line 24 is large (e.g. larger than 2), it is favorable to form an additional second pillar 32 for assisting probe testing.

FIGS. 1J, 1K, 1L are schematic enlarged top views showing the relative positions and configurations of the probe pads 33 and the underlying first conductive pillars 23 of the connectors 35. Referring to FIGS. 1J-1L, the probe pads 33 and the underlying second conductive pillars 32 (not shown) have different shapes according to some alternative embodiments. In these embodiments, the orthogonal projections of the probe pad 33 and the second conductive pillar 32 still fall within the orthogonal projection of the first conductive pillar 23.

In FIG. 1J, the probe pad 33 and the second conductive pillar 32 are not arranged concentrically with the first conductive pillar 23. That is, centers of the probe pad 33 and the second conductive pillar 32 do not overlap with the center of the first conductive pillar 23 on vertical projection. In some embodiment, part of the sidewall 33a of the probe pad 33 is aligned with part of the sidewall 23s of the first conductive pillar 23. In FIG. 1K, the shapes of the probe pad 33 and the underlying second conductive pillar 32 are different from that of the probe pad 33 and the underlying second conductive pillar 32 shown in FIG. 1I. In this embodiment, the probe pad 33 and the underlying second conductive pillar 32 have elliptical shapes. In some embodiment, two endpoints of the probe pad 33 are aligned with part of the sidewall 23s of the first conductive pillar 23. In FIG. 1L, the shapes of the probe pad 33 and the underlying second conductive pillar 32 are different from that of the probe pad 33 and the underlying second conductive pillar 32 shown in FIG. 1I. In this embodiment, the shapes of the probe pad 33 and the underlying second conductive pillar 32 are square. In some embodiment, four endpoints of the probe pad 33 are aligned with part of the sidewall 23s of the first conductive pillar 23.

Referring to FIG. 1M, a testing process is performed to test the electrical performance or functionality of the die units, and through using a probe card, test pins (test probe pins) 40 are applied directly on the probe pads 33 and the second conductive pillars 32. In some embodiments, the probe pads 33 located on the second conductive pillars 32 can receive the test pins or probes 40 and function as a buffering to relieve the stress caused by the test pins 40. Through the testing process performed to the die units of the wafer 10W, the dies units 10 may be tested, selected and categorized. Later, after the singulation process, only the die units that are verified to ascertain the normal functionality are kept and the remained dies 10 are known good dies (KGD). Thus, only KGD dies 10 are kept and undergo subsequent packaging processing to be packaged, and the other dies, which fail the testing, will be rejected and abandoned (not packaged). In some embodiments, the testing process is performed and probe pins 40 of the probe card are brought in contact with the probe pads 33. Since the probe pads 33 are softer than the underlying second conductive pillars 32, the probe pads 33 may buffer and ease the impact brought by the probe pins 40, leading to less scratch or damage.

In some embodiments, with the existence of the second conductive pillars 32, the stacked structures of the connectors 35 are higher than the interconnecting line 24. That is, a distance H2 between the top surface of the connectors 35 and the top surface of the substrate 11 is larger than a distance H3 between the top surface of the interconnecting line 24 and the top surface of the substrate 11. In other words, the total height of the stacked structure of the connector 35 is larger than a height (thickness in the Z-direction) of the interconnecting line 24. Due to the height difference, the probe pins 40 will not contact the interconnecting lines 24 during the testing process, which increase the process window for the testing process and avoids the risks of wrongfully contacting the interconnecting lines 24 or even bridging with the interconnecting lines 24 during the testing. Accordingly, with the presence of the second conductive pillars 32 and the probe pads 33, easier alignment and satisfactory contact (larger probing window) may be established between the probe pins 40 and the connectors 35, which is essential for obtaining precise and accurate testing results from the testing process. In addition, along with the additional conductive pillars, the pitch between the first conductive pillars 23 (the shortest distance between two most adjacent first conductive pillars 23) is further reduced. Following the proper testing process, the known good dies 10 are verified and retained, while defective dies (or malfunctioning dies) are discarded.

Referring to FIG. 1N, a protection layer 50 is further formed on the passivation layer 13 and laterally surrounding the connectors 35 and the interconnecting line 24, after the protection layer 50 is formed, the wafer 10W including the dies 10 is singulated by a die-saw process, and a plurality of dies 10 are obtained. The dies 10 with having the structure shown in FIG. 1N are formed. The protection layer 50 may be a polymer layer. In some embodiments, the protection layer 50 includes PI such as a low temperature PI (LTPI), PBO such as high temperature PBO (HTPBO), BCB, combinations thereof or the like. The material of the protection layer 50 may be the same as or different from that of the second passivation sublayer 13b.

In some embodiments, the protection layer 50 may be formed by the following processes: a protection material is formed on the passivation layer 13, on the probe pads 33 of the connectors 35, and on the interconnecting line 24 by a spin coating process, for example. The protection material layer covers the top surface of passivation layer 13, the top surfaces 33b of the probe pads 33, and the top surface 24a of the interconnecting line 24. A curing process is then performed to cure the protection material layer. In some embodiments in which both the second passivation sublayer 13b and the protection layer 50 are made from PI, the temperature of the curing process of the protection layer 50 is lower than that of the second passivation sublayer 17b. In some embodiments, the temperature of the curing process of the protection material layer is between 170° C. to 320° C., such as 230° C. In some embodiments in which the protection layer 50 includes LTPI, the bubble issue is avoided.

The die 10 includes the substrate 11, the conductive pads 12, the passivation layer 13, the connectors 35, the interconnecting line 24, and the protection layer 50. The connector 35 includes the seed layer 14a, the first conductive pillar 23, and the second conductive pillar 32. The probe pads 33, the sidewalls of the connectors 35 and the interconnecting line 24 are surrounded by and in contact with the protection layer 50. A span of the second conductive pillar 32 is smaller than a span of the first conductive pillar 23, and the orthogonal projection of the second conductive pillar 32 falls within the orthogonal projection of the first conductive pillar 23. The total height of the stacked structure of the connector 35 is larger than a height (i.e. thickness in the Z-direction) of the interconnecting line 24.

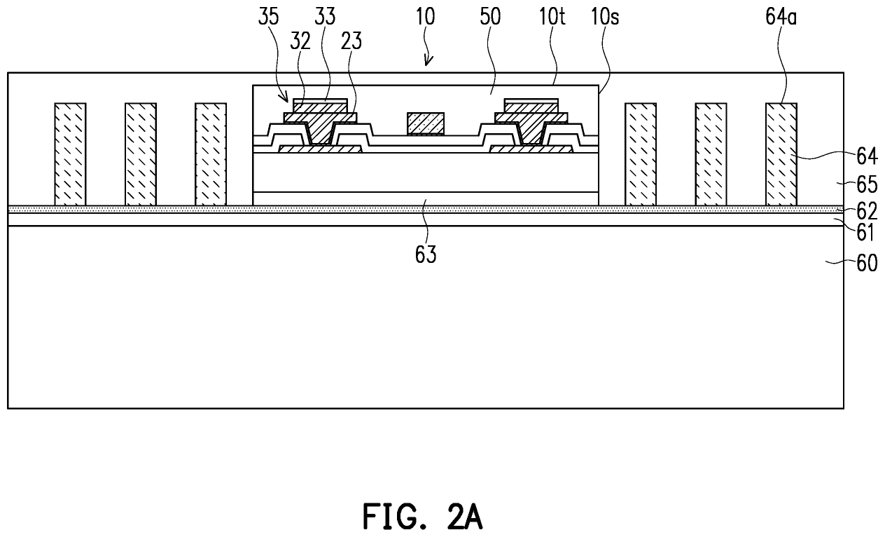

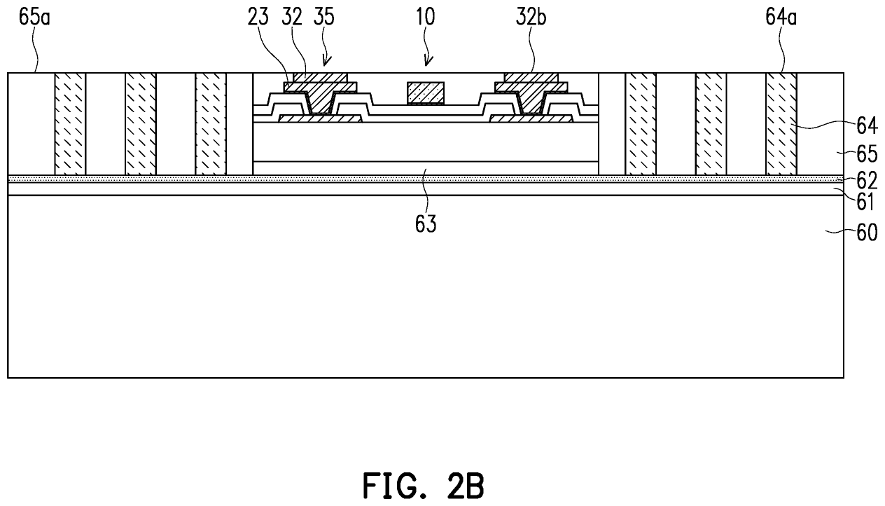

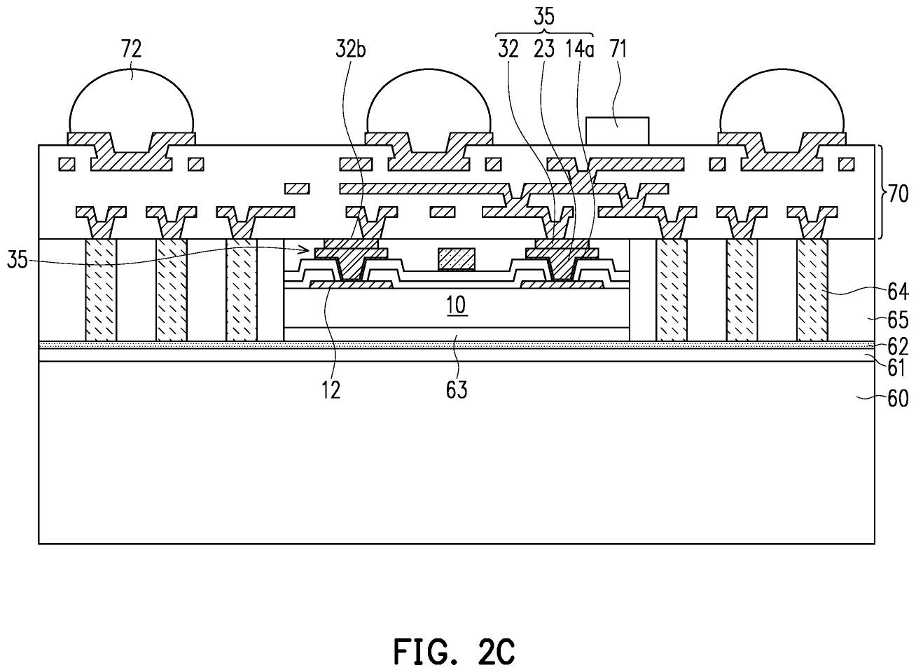

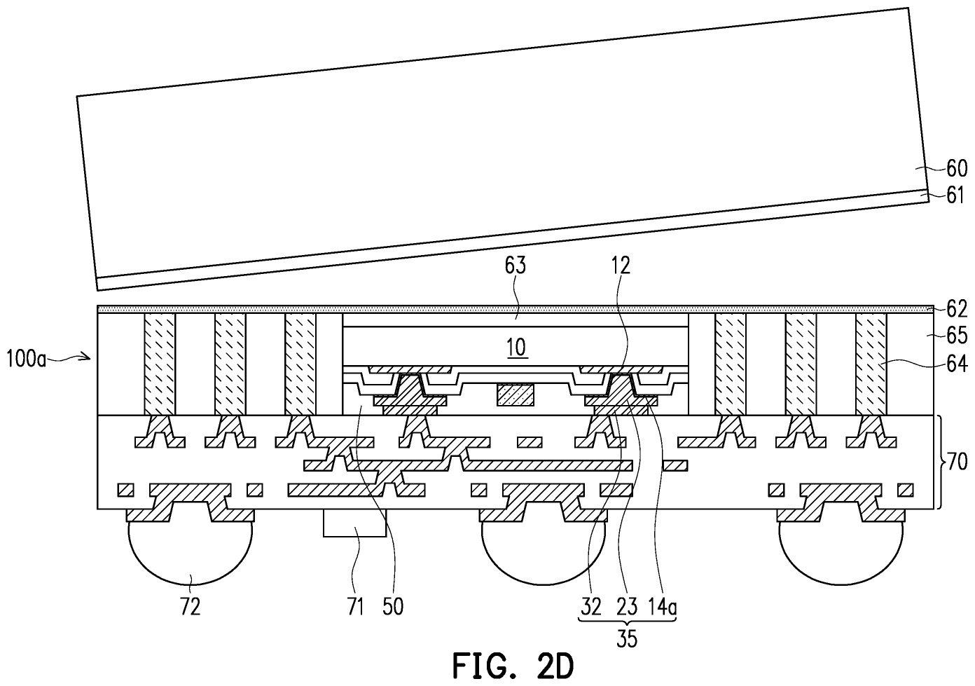

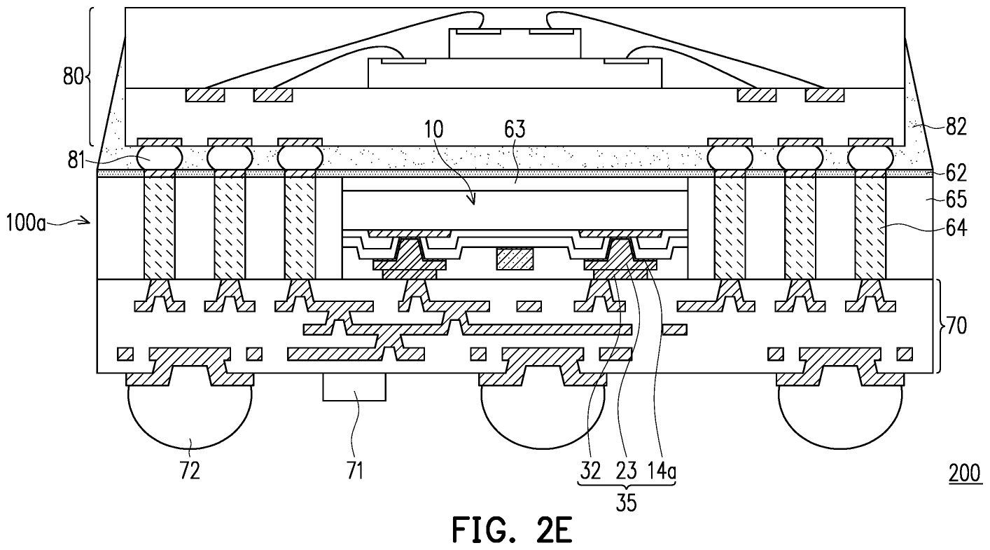

FIG. 2A to FIG. 2E are schematic cross-sectional views illustrating a method of forming a package structure according to some embodiments of the disclosure.

Referring to FIG. 2A, in some embodiments, multiple dies 10 (only one die is shown as an exemplary one) are mounted to a carrier 60. The carrier 60 may be a glass carrier, a ceramic carrier, or the like. In some embodiments, the carrier 60 has a de-bonding layer 61 formed thereon. The de-bonding layer 61 is formed by, for example, a spin coating method. In some embodiments, the de-bonding layer 61 may be formed of an adhesive such as an ultra-violet (UV) glue, a light-to-heat conversion (LTHC) glue, or the like, or other types of adhesives. The de-bonding layer 61 is decomposable under the heat of light to thereby release the carrier 60 from the overlying structures that will be formed in subsequent steps.

Referring to FIG. 2A, in some embodiments, a dielectric layer 62 is optionally formed on the de-bonding layer 61. In some embodiments, the dielectric layer 62 includes or is a polymer layer. The material of the polymer layer includes, for example, PI, PBO, BCB, Ajinomoto buildup film (ABF), solder resist film (SR), or the like. The dielectric layer 62 is formed by a suitable fabrication technique such as spin-coating, lamination, deposition, or the like. In some embodiments, the die 10 is attached to the dielectric layer 62 through an adhesive layer 63 such as a die attach film (DAF), silver paste, or the like.

In some embodiments, before the die 10 is mounted to the carrier 60, through insulator vias (TIVs) 64 are formed on the dielectric layer 62 and located apart from the die(s) 10 and around the die(s) 10. In some embodiments, the TIVs 64 are optionally formed and include integrated fan-out TIVs. In some embodiments, the material of the TIVs 64 include copper, nickel, solder, alloys thereof, or the like. In some embodiments, the TIV 64 includes a seed layer and a conductive layer formed thereon (not shown). The seed layer is, for example, a titanium or/and copper composited layer. The conductive layer is, for example, a copper layer. An illustrative forming method of the TIVs 64 includes forming a photoresist layer such as a dry film resist over the carrier 60 before the die 10 is mounted. Thereafter, openings are formed in the photoresist layer, the openings expose a portion of the top surface of the dielectric layer 62, and the TIVs 64 are then formed in the openings by plating. In some other embodiments, the TIVs 64 further include a barrier layer (not shown) under the seed layer to prevent metal diffusion. The material of the barrier layer includes, for instance, metal nitride such as titanium nitride, tantalum nitride, or a combination thereof.

Still referring to FIG. 2A, an encapsulant 65 is then formed over the carrier 60 to encapsulate the die(s) 10. In some embodiments, the encapsulant 65 includes a molding compound, a molding underfill, a resin such as epoxy, a combination thereof, or the like. In some other embodiments, the encapsulant 65 includes a photo-sensitive polymeric material such as PBO, PI, BCB, a combination thereof, or the like, which may be easily patterned through exposure and development processes. The encapsulant 65 is formed by forming an encapsulant material over the carrier 60 by a suitable fabrication technique such as spin-coating, lamination, deposition, or similar processes. The encapsulant 65 encapsulates the die(s) 10 and fully covers the top surface 10t and sidewalls 10s of the die(s) 10. In some embodiments, the sidewalls of the TIVs 64 are fully surrounded and wrapped by the encapsulant 65.

In some embodiments, the encapsulant 65 covering the die(s) 10 also covers the protection layer 50 and the connectors 35 protected by the protection layer 50, so that the top surface and the sidewalls of the protection layer 50 is covered by and in direct contact with the encapsulant 65.

Referring to FIG. 2A and FIG. 2B, a planarization step, such as a chemical mechanical polish (CMP) step or a grinding step is performed to partially remove the encapsulant 65 so that the top ends 64a of the TIVs 64 and the top surfaces 32b of the second conductive pillars 32 of the connectors 35 are exposed from the encapsulant 65. Depending on the product design, as seen in FIG. 2A, the top ends 64a of the TIVs 64 may be lower than the top surfaces of the probe pads 33 that are located on the second conductive pillars 32. After the planarization step or the grinding step, the probe pads 33 (or even portions of the second conductive pillars 32) are removed until the TIVs 64 are exposed. In some embodiments, as seen in FIG. 2B, after the planarization step, the top ends 64a of TIVs 64 are levelled and coplanar with the top surfaces 32b of the second conductive pillars 32, and are levelled and coplanar with the top surface 65a of encapsulant 65. Accordingly, the probe pads 33 overlapping the second conductive pillars 32 are removed. In the illustrated exemplary embodiments, the planarization step is performed until the top ends 64a of TIVs 64 are exposed. In some embodiments, as the probe pads 33 are removed, the second conductive pillars 32 are exposed. In some embodiment, portions of the second conductive pillars 32 are removed, and the remained portions of the second conductive pillars 32 (with a reduced height) are stacked on the first conductive pillars 23. Therefore, each of the connectors 35 of the die(s) 10 has a two-tiered structure (with a staircase side profile).

Referring to FIG. 2C, a redistribution layer (RDL) structure 70 is formed over and electrically connected to the die 10. In some embodiments, the RDL structure 70 is referred as a “front-side redistribution layer structure”, wherein the “front-side” refers to a side close to the connectors 35 of the die 10. In some embodiments, the RDL structure 70 includes a plurality of dielectric layers and a plurality of redistribution layers stacked alternately. The number of the dielectric layers or the redistribution layers is not limited by the disclosure.

The material of the dielectric layer may be different from the material of the protection layer 50 of the die(s) 10, or the material of the encapsulant 65. In some embodiments, each of the dielectric layers includes a polymeric material or a photo-sensitive material such as PBO, PI, BCB, a combination thereof or the like.

In some embodiments, each of the redistribution layers includes one or more conductive metallic materials, such as copper, nickel, titanium, a combination thereof or the like, and is formed by an electroplating process. In some embodiments, each of the redistribution layers includes a seed layer (not shown) and a metallic layer formed thereon (not shown). In some embodiments, the seed layer includes or is a metallic seed layer such as a copper seed layer, and the metallic layer includes or is a copper layer or a copper alloy layer. In some embodiments, the seed layer includes a first metal layer such as a titanium layer and a second metal layer such as a copper layer over the first metal layer.

In some embodiments, one or more of the redistribution layers include traces and vias interconnecting the traces. For example, the vias vertically penetrate through the dielectric layers to connect the traces of the redistribution layers, and the traces are respectively located on the dielectric layers, and are respectively horizontally extending on the top surface of the dielectric layers.

In some embodiments, the bottommost redistribution layer of the RDL structure 70 contacts the top surface 32b of the second conductive pillars 32. That is, the RDL structure 70 is electrically connected to the interconnection structure (not shown) of the die 10 through the second conductive pillars 32, the first conductive pillars 23, and the conductive pads 12. In some embodiments, the topmost redistribution layer of the RDL structure 70 is referred to as an under-ball metallurgy (UBM) layer for ball mounting. In some embodiments, the topmost redistribution layer may be micro bump for connecting to an integrated passive device (IPD) 71 formed in the subsequent process. In some embodiments, the bottommost redistribution layer is electrically connected to the TIVs 64, such that the TIVs 64 are electrically connected to the die 10 through the RDL structure 70.

Still referring to FIG. 2C, thereafter, a plurality of electrical connectors 72 are formed over and electrically connected to the redistribution layer of the RDL structure 70. In some embodiments, the electrical connectors 72 are referred as conductive terminals. In some embodiments, the electrical connectors 72 may be ball grid array (BGA) connectors, solder balls, controlled collapse chip connection (C4) bumps, or a combination thereof. In some embodiments, the material of the electrical connectors 72 includes copper, aluminum, lead-free alloys (e.g., gold, tin, silver, aluminum, or copper alloys) or lead alloys (e.g., lead-tin alloys). The electrical connectors 72 may be formed by a suitable process such as evaporation, plating, ball dropping, screen printing and reflow process, a ball mounting process or a C4 process. In some embodiments, metal posts or metal pillars (not shown) may further be formed between the redistribution layer and the electrical connectors 72. The electrical connectors 72 are electrically connected to the connectors 35 of the die 10 through the RDL structure 70.

The IPD 71 is formed over and electrically connected to the redistribution layer of the RDL structure 70 through the solder bumps (not shown). The IPD 71 may be a capacitor, a resistor, an inductor or the like, or a combination thereof. The number of the IPD 71 is not limited to that is shown in FIG. 2C, but may be adjusted according to the design of the product.

Referring to FIG. 2D, the de-bonding layer 61 is decomposed under the heat of light, and the carrier 60 is then released. The dielectric layer 62 may be optionally remained. A package structure 100a is thus completed. The package structure 100a is also referred as a fan-out package structure. The package structure 100a includes the die 10, the encapsulant 65, the RDL structure 70 and the electrical connectors 72. The die 10 includes the connectors 35. The connectors 35 are in electrical contact with the conductive pads 12, and further electrically connected to the interconnection structure (not shown) of the die 10. The connector 35 of the die 10 includes the seed layer 14a, the first conductive pillar 23, and the second conductive pillar 32 on the first conductive pillar 23. In some embodiments, the top surface and sidewalls of the connectors 35 are covered by and in physical contact with the protection layer 50. In some embodiments, the sidewalls of the protection layer 50 is covered by and in physical contact with the encapsulant 65.

Referring to FIG. 2E, the package structure 100a may further be electrically coupled with a package structure 80 to form a package-on-package (POP) device 200, but the disclosure is not limited thereto.

In some embodiments, after the package structure 100a is formed, the dielectric layer 62 may be patterned to form openings by laser drilling process, for example. The openings expose portions of the bottom surfaces of the TIVs 64. Thereafter, electrical connectors 81 fill into the openings of the dielectric layer 62, electrically connecting the TIVs 64 of the package structure 100a with the package structure 80. The package structure 80 may be or includes any compatible package structure(s) according to the functional demands of the POP device 200. In some embodiments, the package structure 80 includes memories such as dynamic random access memories (DRAMs), static random access memories (SRAMs), high performance memories or combinations thereof.

In some embodiments, an underfill layer 82 is further formed to fill the space between the package structure 100a and the package structure 80 and surround the electrical connectors 81. The POP device 200 including the package structure 100a and the package structure 80 is thus completed, wherein the package structure 100a and the package structure 80 are connected through the connectors 81. The POP device 200 shown in FIG. 2E is merely for illustration, and the disclosure is not limited thereto.

In the foregoing embodiments, the combination of the dies packed in a package structure is merely for illustration, and the disclosure is not limited thereto. One or more dies 10 may be packed into a package structure individually or in any kind of combination. Further, although fan-out package structure is illustrated, the disclosure is not limited thereto. The die 10 may also be used to form other kind of package structure, such as fan-in package.

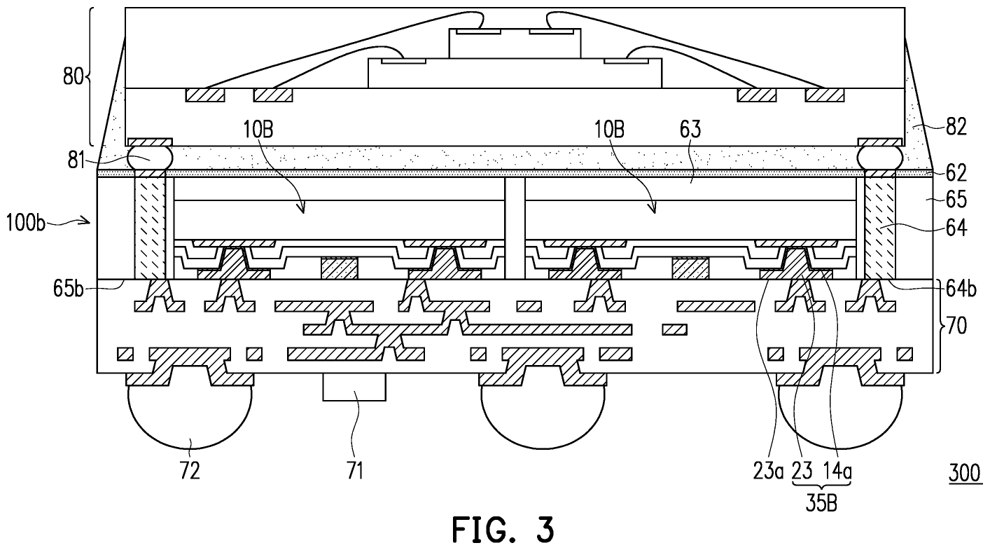

FIG. 3 is a schematic cross-sectional view illustrating a package structure according to some embodiments of the disclosure.

The package structure 100b has similar components and similar arrangement like those of the package structure 100a (shown in FIG. 2E), and multiple dies 10B are included in the package structure 100b. In some embodiments, the dies 10B have configurations different from that of the die 10 as described in the previous paragraphs. Following the same manufacturing processes described in the previous paragraphs, the dies 10B is formed with the connectors 35B. It is understood that although two dies 10B are shown in the package structure 100b, but the quantity of the dies is not limited by the drawings or disclosure herein.

Referring to FIG. 3, in some embodiments, the package structure 100b has connector 35B different from the connector 35 of the die 10 shown in FIG. 2E. In FIG. 3, in some embodiments, the connector 35B of the die 10B includes the seed layer 14a and the first conductive pillar 23. Specifically, the dies 10B may be fabricated following the manufacturing processes as described in the previous paragraphs, and during the planarization step (or the grinding step), not only portions of the encapsulant 65 and the protection layer 50 are removed, the second conductive pillar 32 is also removed simultaneously during the planarization step. In some embodiments, during the planarization step, the second conductive pillars 32 are entirely removed, and only the first conductive pillars 23 are remained. As shown in FIG. 3, the bottom ends (bottom surfaces) 64b of TIVs 64 are levelled with and coplanar with the bottom surfaces 23a of the first conductive pillars 23 and the bottom surface 65b of the encapsulant 65. In the illustrated exemplary embodiments, the planarization step is performed until the first conductive pillars 23 are exposed. In some embodiments, portions of the first conductive pillars 23 may be removed, but the remained portion of the first conductive pillars 23 (together with the seed layer 14a) form the connectors 35B. In some embodiments, the connectors 35B of the dies 10B do not have a two-tiered structure. In some embodiments, the bottommost redistribution layer of the RDL structure 70 contacts the top surface 23a of the first conductive pillars 23. That is, the RDL structure 70 is electrically connected to the interconnection structure (not shown) of the die 10 through the first conductive pillars 23 and the conductive pads 12.

In the embodiments of the disclosure, the formation process of the connectors includes at least two photolithography and exposure processes using two different photomasks followed by etching steps. Through the two-staged process, the height of the connectors is higher than the height of the interconnecting line (i.e. thickness in the Z-direction). The interconnecting line may not connect to the probe pins, thus avoiding the risk of bridging which may occur during the probe testing before forming the package structure.

In accordance with some embodiments of the disclosure, the semiconductor die includes a semiconductor substrate, a plurality of conductive pads over the semiconductor substrate, a passivation layer over the semiconductor substrate and partially covering the plurality of conductive pads, an interconnecting line disposed on the passivation layer, and a plurality of connectors disposed on and electrically connected to the plurality of conductive pads. Each of the plurality of connectors includes a stacked structure of a first conductive pillar and a second conductive pillar disposed directly on the first conductive pillar, wherein a span of the second conductive pillar is smaller than a span of the first conductive pillar, and an orthogonal projection of the second conductive pillar falls within an orthogonal projection of the first conductive pillar, and the interconnecting line is located beside and spaced apart from the plurality of connectors.

In accordance with alternative embodiments, a method of forming a semiconductor die comprises the following steps. Providing a semiconductor substrate with conductive pads disposed on the semiconductor substrate. Forming a passivation layer over the semiconductor substrate and partially covering the conductive pads with portions of the conductive pads exposed from the passivation layer. Forming connectors on the exposed portions of the conductive pads, comprising. Performing a testing process by applying test probes to the second conductive pillars of the connectors. A method of forming connectors comprises the following steps. Forming a seed layer over the passivation layer and on the exposed portions of the conductive pads. Forming a first patterned photoresist layer with first openings over the seed layer, exposing portions of the seed layer. Forming a first conductive material into the first openings to form first conductive pillars on the exposed portions of the seed layer within the first openings. Removing the first patterned photoresist layer. Forming a second patterned photoresist layer with second openings over the seed layer and on the first conductive pillars, exposing portions of the first conductive pillars. Forming a second conductive material into the second openings to form second conductive pillars on the exposed portions of the first conductive pillars. Removing the second patterned photoresist layer.

In accordance with some embodiments, a method of forming a package structure, comprises the following steps. Forming a semiconductor die. Forming an encapsulant aside the semiconductor die to encapsulate sidewalls of the semiconductor die. Performing a planarization process to remove a portion of the encapsulant, a portion of the protection layer, and the probe pad to expose the second conductive pillar. Forming a redistribution (RDL) structure on the semiconductor die and the encapsulant. Forming a conductive terminal, electrically connected to the semiconductor die through the RDL structure. A method of forming the semiconductor die comprises the following steps. Providing a substrate with conductive pads disposed on the substrate. Forming connectors on and electrically connected to the conductive pads. A method of forming the connectors comprises the following steps. Forming a seed layer on the conductive pads and the substrate. Forming first conductive pillars on the conductive pads. Forming second conductive pillars on the first conductive pillars respectively, wherein a span of the second conductive pillar is smaller than a span of the first conductive pillar, and an orthogonal projection of the second conductive pillar falls within an orthogonal projection of the first conductive pillar. Forming probe pads on the second conductive pillars. Performing a testing process by applying test probes to the second conductive pillars of the connectors. Forming a protection layer laterally surrounding the connector.

The foregoing outlines features of several embodiments so that those skilled in the art may better understand the aspects of the disclosure. Those skilled in the art should appreciate that they may readily use the disclosure as a basis for designing or modifying other processes and structures for carrying out the same purposes and/or achieving the same advantages of the embodiments introduced herein. Those skilled in the art should also realize that such equivalent constructions do not depart from the spirit and scope of the disclosure, and that they may make various changes, substitutions, and alterations herein without departing from the spirit and scope of the disclosure.

What is claimed is:

1. A semiconductor die, comprising:
a semiconductor substrate;
a plurality of conductive pads over the semiconductor substrate;
a passivation layer over the semiconductor substrate and partially covering the plurality of conductive pads;
an interconnecting line disposed on the passivation layer; and
a plurality of connectors disposed on and electrically connected to the plurality of conductive pads, each of the plurality of connectors includes a stacked structure of a first conductive pillar and a second conductive pillar disposed directly on the first conductive pillar, wherein a span of the second conductive pillar is smaller than a span of the first conductive pillar, and an orthogonal projection of the second conductive pillar falls within an orthogonal projection of the first conductive pillar, and the interconnecting line is located beside and spaced apart from the plurality of connectors.

2. The semiconductor die of claim 1, further comprising:
a protection layer disposed on the semiconductor substrate and covering sidewalls of the plurality of connectors and sidewalls of the interconnecting line.

3. The semiconductor die of claim 1, wherein each of the plurality of connectors further comprises:
a probe pad disposed on the second conductive pillar, wherein a width of the probe pad is substantially equal to a width of the second conductive pillar.

4. The semiconductor die of claim 3, wherein the probe pad is located at a level higher than that of the interconnecting line.

5. The semiconductor die of claim 1, wherein a material of the first conductive pillar and a material of the second conductive pillar are the same.

6. The semiconductor die of claim 1, wherein the first conductive pillar and the second conductive pillar are arranged concentrically.

7. A method of forming a semiconductor die, comprising:
providing a semiconductor substrate with conductive pads disposed on the semiconductor substrate;
forming a passivation layer over the semiconductor substrate and partially covering the conductive pads with portions of the conductive pads exposed from the passivation layer;
forming connectors on the exposed portions of the conductive pads, comprising:
forming a seed layer over the passivation layer and on the exposed portions of the conductive pads;
forming a first patterned photoresist layer with first openings over the seed layer, exposing portions of the seed layer;
forming a first conductive material into the first openings to form first conductive pillars on the exposed portions of the seed layer within the first openings;
removing the first patterned photoresist layer;
forming a second patterned photoresist layer with second openings over the seed layer and on the first conductive pillars, exposing portions of the first conductive pillars;
forming a second conductive material into the second openings to form second conductive pillars on the exposed portions of the first conductive pillars; and
removing the second patterned photoresist layer; and
performing a testing process by applying test probes to the second conductive pillars of the connectors.

8. The method of claim 7, further comprising:
forming a protection layer laterally surrounding the connectors and covering top surfaces and sidewalls of the connectors after performing the testing process.

9. The method of claim 8, further comprising:
performing a singulation process cutting through the protection layer and the semiconductor substrate to form a plurality of semiconductor dies.

10. The method of claim 7, wherein forming connectors on the exposed portions of the conductive pads further comprises:
forming an interconnecting line on the seed layer after forming the first patterned photoresist layer and before forming the second patterned photoresist layer, wherein the interconnecting line is formed beside and spaced apart from the connectors.

11. The method of claim 10, wherein a top surface of each of the connectors is higher than a top surface of the interconnecting line.

12. The method of claim 7, further comprising:
forming probe pads on the second conductive pillars respectively, wherein a span of the probe pad is substantially same as a span of the second conductive pillar.

13. The method of claim 7, wherein a width of the first opening is larger than a width of the second opening.

14. A method of forming a package structure, comprising:
forming a semiconductor die, comprising:
providing a substrate with conductive pads disposed on the substrate;
forming a passivation layer over the substrate and partially covering the conductive pads with portions of the conductive pads exposed from the passivation layer; and
forming connectors on the conductive pads, comprising:
forming a seed layer on the conductive pads and over the substrate;
forming first conductive pillars on the conductive pads;
forming second conductive pillars on the first conductive pillars respectively, wherein a span of the second conductive pillar is smaller than a span of the first conductive pillar, and an orthogonal projection of the second conductive pillar falls within an orthogonal projection of the first conductive pillar;
forming probe pads on the second conductive pillars respectively;
performing a testing process by applying test probes to the second conductive pillars of the connectors; and
forming a protection layer covering the connectors;
forming an encapsulant over the semiconductor die to encapsulate the semiconductor die;
performing a planarization process to remove a portion of the encapsulant, a portion of the protection layer, and the probe pads to expose the second conductive pillars of the connectors;
forming a redistribution (RDL) structure on the semiconductor die and the encapsulant; and
forming a conductive terminal, electrically connected to the semiconductor die through the RDL structure.

15. The method of claim 14, wherein the method of forming the first conductive pillars comprises:
forming a seed layer over the passivation layer and on the exposed portions of the conductive pads;
forming a first patterned photoresist layer with first openings over the seed layer, exposing portions of the seed layer;
forming a first conductive material into the first openings to form first conductive pillars on the exposed portions of the seed layer within the first openings; and
removing the first patterned photoresist layer.

16. The method of claim 15, wherein the method of forming the second conductive pillars comprises:
forming a second patterned photoresist layer with second openings over the seed layer and on the first conductive pillars, exposing portions of the first conductive pillars;
forming a second conductive material into the second openings to form second conductive pillars directly on the exposed portions of the first conductive pillars; and
removing the second patterned photoresist layer.

17. The method of claim 14, wherein a width of the first openings is larger than a width of the second openings.

18. The method of claim 14, further comprising:
forming a plurality of through insulator vias (TIVs) penetrating through the encapsulant, wherein the plurality of TIVs are arranged aside and around the semiconductor die.

19. The method of claim 14, wherein the RDL structure is electrically connected with the conductive pads of the die and physically contacts the second conductive pillars.

20. The method of claim 14, wherein performing the planarization process further comprises:
removing the second conductive pillars and exposing the first conductive pillars.
